(19) United States
(12) Patent Application Publication
(10) Pub. No.: US 2008/0186017 A1
(43) Pub. Date: Aug. 7, 2008

(54) Measuring Device for Angle and/or Path Measurement

(76) Inventors: Frank Buerger, Dueren (DE); Karin Wittkamp, Duesseldorf (DE); Waldemar Stephan, Dortmund (DE); Christoph Peiffer, Grevenbroich (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 11/629,847

(22) PCT Filed: Jun. 8, 2005
(86) PCT No.: PCT/EP05/52642

§ 371 Date: Nov. 14, 2007

(30) Foreign Application Priority Data
Jun. 17, 2004 (DE) 10 2004 029 339.2

(51) Int. Cl. G01B 7/30; H01L 43/06

(52) U.S. Cl. 324/207.2; 324/207.25

(57) ABSTRACT

A measuring device for angle and/or path measurement comprises a moving element. The moving element has connected therewith a magnetic field generator. Further, a magnetic field sensor is provided which picks up the magnetic field generated by the magnetic field generator. For evaluating the picked-up magnetic field, the magnetic field sensor is connected with an evaluator. For providing as space-saving and inexpensive a measuring device as possible, the magnetic field generator comprises at least two stud magnets.

The invention relates to a measuring device for angle and/or path measurement. In particular, the invention relates to a measuring device for angle and/or path measurement for actuators in motor vehicles.

In motor vehicle elements, angle measurement and/or determination of a position of a pivot axis are required for controlling throttle or exhaust-gas dampers, for example. Here, the position of the damper must be exactly determined. A device for determining the angle of rotation, i.e. the opening angle, of a throttle damper is known from DE 199 03 490. Here, the throttle damper is connected with a pivot axis, and via a plurality of intermediate members with a ring magnet arranged concentrically with the pivot axis. The ring magnet is carried along when the throttle damper is pivoted. In a housing cover two magnetic field sensors, such as Hall sensors, are arranged. The two sensors are arranged outside the ring magnet at an offset of 180° to each other. The two sensors generate two angle-dependent signals. The developed view of the magnetic field curves generated by the two sensors is essentially sinusoidal, wherein the curves are essentially linear in an angular range of ±45°. Providing of a ring magnet comprising two sensors arranged outside the ring magnet requires a large installation space. This is in particular disadvantageous in the detection of the angle of rotation of throttle and exhaust-gas dampers since they are arranged in a region of the engine which offers only little space.

It is an object of the invention to provide a measuring device for angle and/or path measurement which requires little installation space and is inexpensive to manufacture.

According to the invention, this object is achieved with the features of claim 1.

The measuring device for angle and/or path measurement, which is in particular suitable for actuators in motor vehicles, comprises a moving element, such as a gearwheel or a sliding carriage. The moving element has connected therewith a magnetic field generator. The magnetic field generator has associated therewith a magnetic field sensor which picks up the magnetic field generated by the magnetic field generator and/or generates signals in dependence on the detected magnetic field. Here, the magnetic field changes due to the relative movement between the magnetic field generator and the magnetic field sensor, wherein a signal is generated in dependence on the change in the magnetic field. The signal generated by the magnetic field sensor is transmitted to an evaluation means. Here, the evaluation means may be part of an evaluation and/or control electronics, for example, wherein the control electronics controls the motor vehicle actuator, for instance.

According to the invention, the magnetic field generator comprises at least two stud magnets arranged in spaced relationship to each other. The at least two stud magnets are arranged at an angle to each other at a pivotable moving element. Further, the stud magnets may be arranged at a linear distance to each other at a displaceable moving element, such as a sliding carriage. The two stud magnets arranged in spaced relationship to each other generate a magnetic field, wherein the magnetic field strength changes in dependence on the location of the stud magnets relative to the magnetic field sensor. Thereby, the location of the moving element can be determined. Here, it is possible that the sensor knows the curve shape of the magnetic field depending on the location of the stud magnets, and/or that the curve shape is stored in the evaluation unit such that the position of the moving element can be derived from said curve shape. Preferably, the stud magnets are selected with respect to their size and magnetic strength such that a quasi-linear magnetic field exists between the two stud magnets in the moving region of interest. This offers the advantage that storage and/or determination of the magnetic field curve are not necessary, and thus a magnetic field sensor of simple configuration and an evaluation unit of a correspondingly simple design can be used.

Providing of stud magnets offer the advantage that these are small components, and the circular, in particular diametrically magnetized magnets known from prior art may be omitted. The measuring device according to the invention thus requires only a small installation space and can be manufactured at very low costs.

In a particularly preferred embodiment of the measuring device according to the invention, only a single magnetic field sensor is provided. This helps to further reduce the installation space and the costs of the measuring device.

Preferably, the magnetic field sensor is a Hall sensor, in particular a node-programmable Hall sensor. With the aid of Hall sensors the magnetic field can be exactly detected.

Preferably, the stud magnets are aligned such that their north-south alignment essentially extends perpendicularly to the direction of movement. Thereby, it is ensured that the magnetic field existing between the two stud magnets can be well detected by the magnetic field sensor.

In a particularly preferred embodiment of the measuring device, the measuring device is a rotation angle detection device for throttle and/or exhaust gas dampers in motor vehicles. Here, a pivot axis is provided which is preferably directly connected with the damper. For detection of the pivot angle of the pivot axis, the magnetic field generator configured in the form of at least two stud magnets is arranged in spaced relationship to the centerline of the pivot axis. Here, the two stud magnets are preferably arranged on a circular line. The magnetic field sensor is arranged adjacent to the stud magnets and/or the magnetic field generated by the stud magnets. Thus pivoting of the pivot axis causes a relative movement between the stud magnets and the magnetic field sensor. Thereby, the magnetic field picked up by the magnetic field sensor changes. In dependence on the change in the magnetic field, the magnetic field sensor generates an angle-dependent signal. For determination of the exact angle, an evaluation unit may be necessary, which correspondingly processes the signal of the magnetic field sensor.

In a particularly preferred embodiment, the magnetic field sensor is arranged in particular at an axial distance to the magnetic field generators such that in the region of the magnetic field sensor the magnetic field lines of the two magnetic field generators show a smooth transition to each other. This preferred arrangement according to the invention is based on the realization that the field lines, when showing a small distance to each other, extend at a very acute angle to each other, i.e. they do not show a smooth transition. When the axial distance is increased, the transition between the field lines becomes smoother, but an increase in the distance results in a decrease of the field strength. Thus, in dependence on the magnetic field strength generated by the magnets, an optimum distance can be determined at which, in particular in dependence on the sensitivity of the magnetic field sensor, the magnetic field strength is still sufficient and thus as smooth a transition of the magnetic field lines as possible occurs. The smooth transition is in particular an angle between the intersecting magnetic field lines of the two magnetic fields of more than 60°, in particular more than 90° and most preferably more than 120°. Here, it must be taken into account that the magnetic fields generated by the two magnetic field generators depend on the outer dimensions, in particular the diameter of the magnetic field generators, the material and their axial extension. The optimum location of the magnetic field sensor relative to the magnetic field generators can be experimentally determined. In doing so, the magnetic field sensor is arranged such that in the angular range of interest an essentially linear shape of the magnetic field lines is produced.

An embodiment of the invention will now be described in greater detail with reference to the drawings in which:

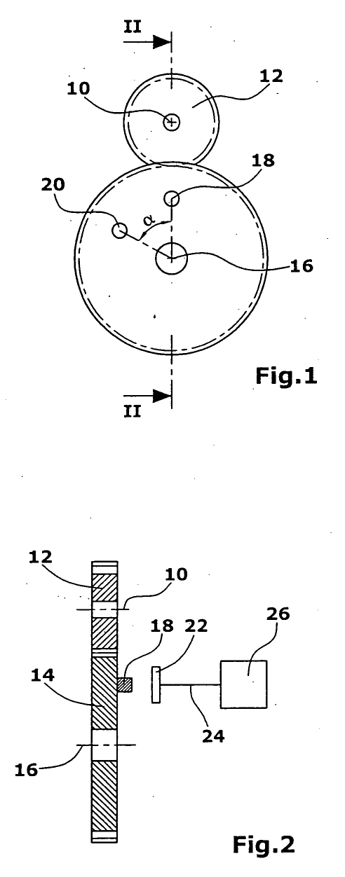

FIG. 1 shows a schematic top view of an angle measurement device,

FIG. 2 shows a schematic side view along line II-II of FIG. 1,

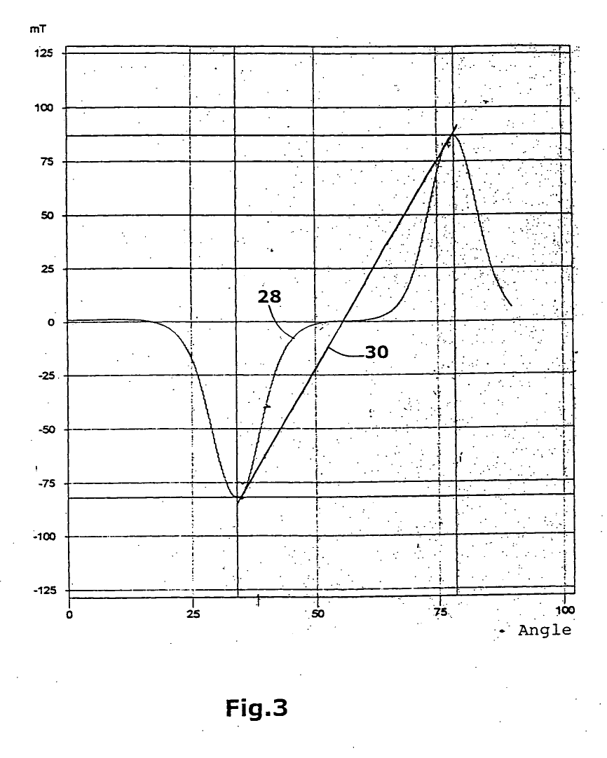

FIGS. 3-5 show diagrams of the magnetic field strength versus the angle at different distances between two stud magnets, and

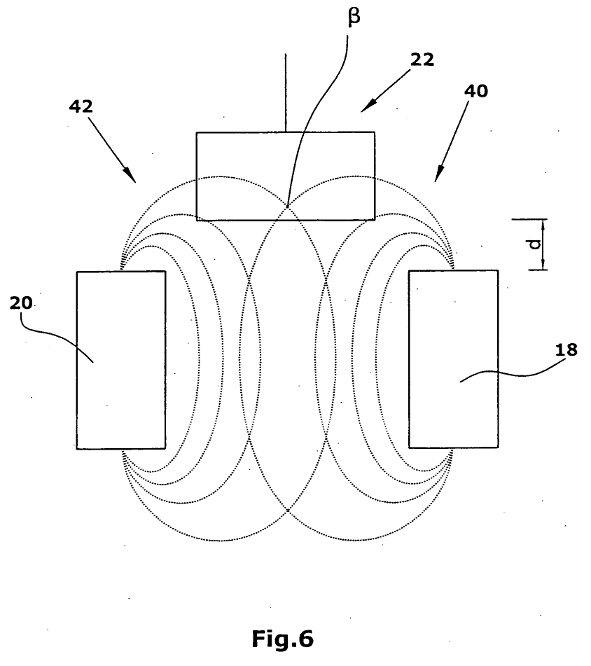

FIG. 6 shows a schematic representation of the arrangement of a magnetic field sensor relative to two stud magnets.

An angle measuring device, which is suitable for measuring an angle of rotation of a throttle damper or an exhaust gas damper, for example, comprises a shaft 10 connected with an actuating motor, said shaft 10 carrying a gearwheel 12. The gearwheel 12 clampingly meshes with a gearwheel 14 which is connected with a pivot axis 16. The pivot axis 16 is connected with an axis of the dampers, for example. Likewise, the one or a plurality of dampers may be directly provided on the pivot axis 16.

For determining a pivot angle of the pivot axis 16 and thus the location of a damper, for example, the gearwheel 14, which is a moving element, has connected therewith two stud magnets 18,20 serving as magnetic field generators. In the illustrated embodiment, the two stud magnets 18,20 are arranged on a common circular line at an angular relationship a to each other. The stud magnets 18,20 are arranged such that in the one stud magnet the north pole and in the other stud magnet the south pole points towards a magnetic field sensor 22 disposed opposite the stud magnets. Between the two stud magnets 18,20 a magnetic field thus exists which is detected by the magnetic field sensor 22, e.g. a Hall sensor. Via a line 24 the magnetic field sensor is connected with an evaluation unit 26, in particular an evaluation and/or control electronics.

In the diagrams shown in FIGS. 3-5 the shape of the magnetic field curve depending on the angle was plotted, wherein the two stud magnets 18,20 were connected with the gearwheel 14 at different angles α to each other.

The stud magnets are circular cylindrical stud magnets having a diameter of 2 mm and a length of 4 mm. The magnets were axially magnetized. When measured in an abutting state, the magnets had a field strength of 250 mT. SmC 05/17 is a particularly suitable material for the stud magnets. Such stud magnets were used in all three examples described below.

According to FIG. 3, the stud magnets 18,20 were arranged at an angle of α=45° to each other.

As shown in FIG. 3, the magnetic field curve extends in the angular range of approximately −82 mT to +87 mT. According to the invention, the exact curve 28 can be stored in the magnetic field sensor and/or the evaluation means. In a simple embodiment of the invention, which suffices when the angle of rotation need not be exactly determined, the curve 28 may be linearized to form a straight line 30. Although in this case the measurement becomes inexact to a certain extent, this offers the advantage that the angle detection in dependence on the measured magnetic field is considerably easier.

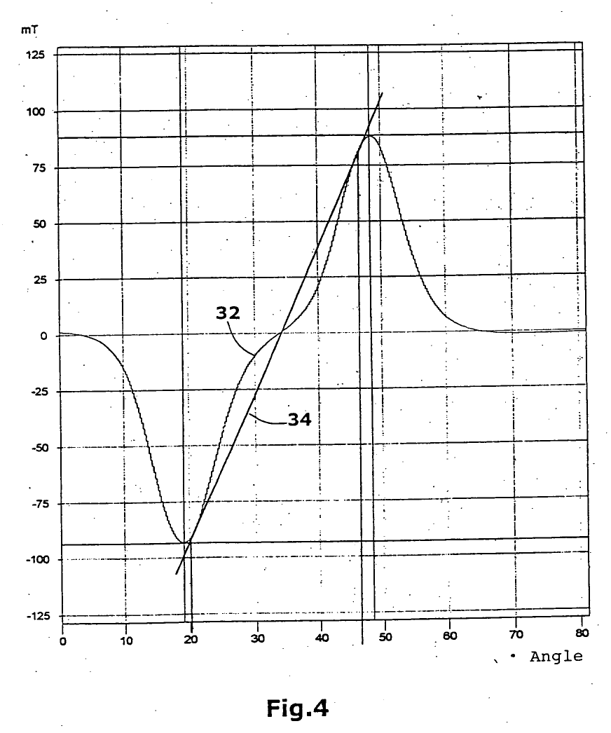

The diagram shown in FIG. 4 is based on a test in which the two stud magnets 18,20 were arranged at an angle α=35° to each other. As in shown in the Figure, the deviation between the actually plotted curve 32 and the linearized curve 34 is considerably smaller such that in an angular range of 350 the linearized curve 34 having a relatively high accuracy can be stored.

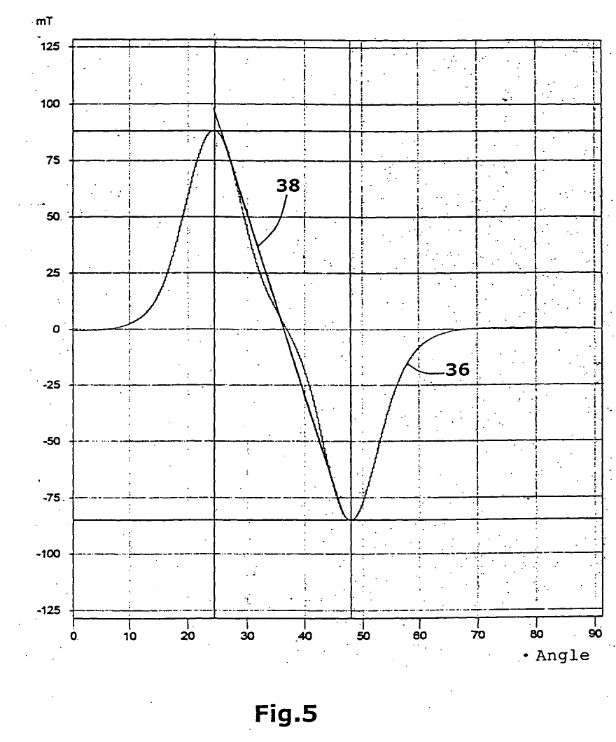

The diagram shown in FIG. 5 was determined on the basis of an angular relationship of α=23°. Here, it was determined that the difference between the actual magnetic field curve 36 and the linearized curve 38 is even smaller such that in such an angular range the linearized curve can be used, in particular for actuators in a motor vehicle.

In a particularly preferred embodiment of the invention, in which in particular the measuring results shown in FIGS. 4 and 5 can be achieved, the magnetic field sensor 22 (FIG. 5) is arranged at an axial distance d of 5-10 mm relative to the two stud magnets 18,20. Consequently, the magnetic field sensor is disposed in a region in which a smooth transition occurs between the magnetic field lined 40,42 of the two stud magnets 18,20. In particular, in this region of a smooth transition an angle β is larger than 60°, preferably larger than 90°, and most preferably larger than 120°.

What is claimed is :

1. A measuring device for angle and/or path measurement, comprising:
a moving element,
a magnetic field generator connected with said moving element,
a magnetic field sensor picking up the magnetic field generated by said magnetic field generator, and
an evaluation unit connected with said magnetic field sensor,
wherein the magnetic field generator comprises at least two stud magnets arranged in spaced relationship to each other.

2. The measuring device according to claim 1, wherein said stud magnets are selected in particular with regard to their size and/or their strength such that a quasi-linear magnetic field exists between the stud magnets.

3. The measuring device according to claim 1, wherein said magnetic field sensor is a Hall sensor, in particular a node-programmable Hall sensor.

4. The measuring device according to claim 1, wherein the alignment of the stud magnets essentially extends perpendicularly to their direction of movement.

5. The measuring device according to claims 1, wherein said moving element is a gearwheel or a disk.

6. The measuring device according to claims 1, wherein said moving element comprises a pivot axis, and the stud magnets are arranged on a circular line in spaced relationship to the pivot axis.

7. The measuring device according to claim 1, wherein an axial distance (d) between the magnetic field generators and the magnetic field sensor is selected such that the magnetic field lines of the magnetic field generators show a smooth transition to each other.
